(19) United States
(12) Patent Application Publication
(10) Pub. No.: US 2011/0090623 A1
(43) Pub. Date: Apr. 21, 2011

(54) ELECTRONIC DEVICE WITH SUPPORT

(75) Inventor: ZHI-HUA LIU, Shenzhen City (CN)

(73) Assignees: HONG FU JIN PRECISION INDUSTRY (ShenZhen) CO., LTD, Shenzhen City (CN); HON HAI PRECISION INDUSTRY CO., LTD., Tu-Cheng (TW)

(21) Appl. No.: 12/649,577

(22) Filed: Dec. 30, 2009

(30) Foreign Application Priority Data
Oct. 19, 2009 (CN) 200910308461.4

(51) Int. Cl. H05K 7/00

(52) U.S. Cl. 361/679.01

(57) ABSTRACT

An electronic device includes a housing and a support. The housing includes a bottom surface and a mounting hole defined in the bottom surface. The support includes a fixing board fixed in the mounting hole of the housing and a foot pad. The fixing board defines a through hole. The foot pad includes a latching hook engaging the fixing board via the through hole. The latching hook includes a sliding portion and a hook portion fixed to a free end of the sliding portion. The through hole includes a receiving portion passing through the hook portion and a latching portion communicating with the receiving portion. The sliding portion is fixed in the latching portion, and the hook portion is correspondingly hooked onto the fixing board.

### BACKGROUND

1. Technical Field

The present disclosure generally relates to electronic devices and, particularly, to an electronic device with a plurality of supports.

2. Description of Related Art

Electronic devices such as computers and notebook computers often utilize a plurality of supports. The electronic devices commonly include a housing and a plurality of mounting holes defined in a bottom surface thereof. The supports are fixed to the corresponding mounting holes. In use, the electronic devices are placed on a work surface. At this time, the bottom surface of the electronic devices is kept from contacting with the work surface by means of using the supports, such that heat dissipation of the electronic device is increased. The supports are made of rubber or other soft material, providing friction force between the device and the work surface.

However, often, the supports are fixed to the mounting holes of the bottom surface by adhesive or heat melting. Thus, the supports are prone to detachment from the bottom surface of the electronic device in time, or due to changes in temperature or humidity.

Therefore, there is room for improvement within the art.

### BRIEF DESCRIPTION OF THE DRAWINGS

The components in the drawings are not necessarily drawn to scale, the emphasis instead being placed upon clearly illustrating the principles of the present disclosure. Moreover, in the drawings, like reference numerals designate corresponding parts throughout several views, and all the views are schematic.

FIG. 1 is a cutaway view of an embodiment of an electronic device having a support, the support including a fixing board and a foot pad.

FIG. 2 is an enlarged, isometric view of the support of the electronic device of FIG. 1.

FIG. 3 is an exploded, isometric view of the support of FIG. 2.

FIG. 4 is a cross-section of the support of FIG. 2, taken along line IV-IV.

FIG. 5 is a cross-section of the support of FIG. 2, taken along line V-V.

FIG. 6 is similar to FIG. 3, but viewed from another aspect.

FIG. 7 is an isometric view of the support of FIG. 6 showing the foot pad being installed onto the fixing board of the support.

### DETAILED DESCRIPTION

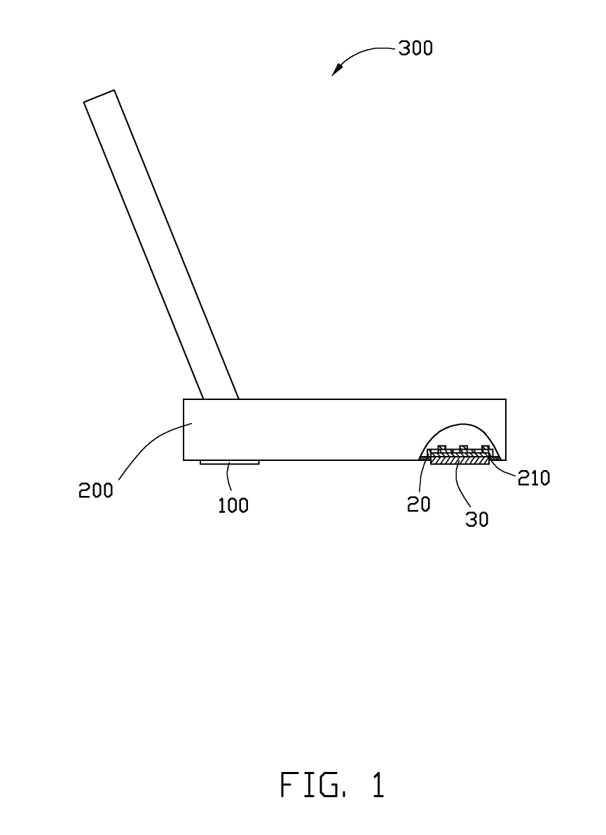

Referring to FIG. 1, a plurality of supports 100 according to an embodiment are utilized in an electronic device 300, such as a notebook computer. The electronic device 300 includes a housing 200. The housing 200 defines a plurality of mounting holes 210 in a bottom surface thereof. The supports 100 are fixed in the mounting holes 210 to support the electronic device 300. The electronic device 300 includes various modules for performing corresponding function and features, however for simplicity, only the module related to the supports 100 will be described. In alternative embodiments, the electronic device 300 can be other electronic devices, such as a computer host.

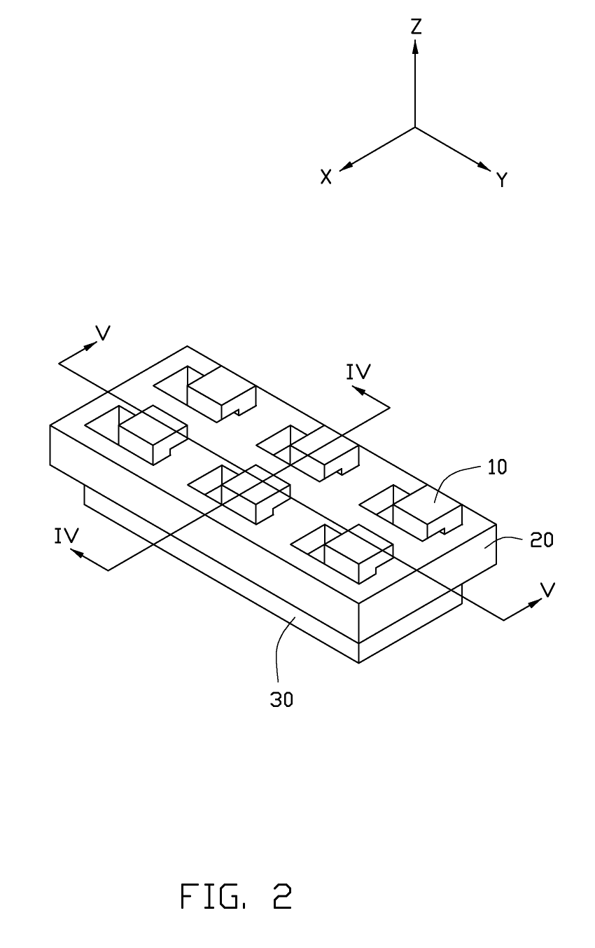

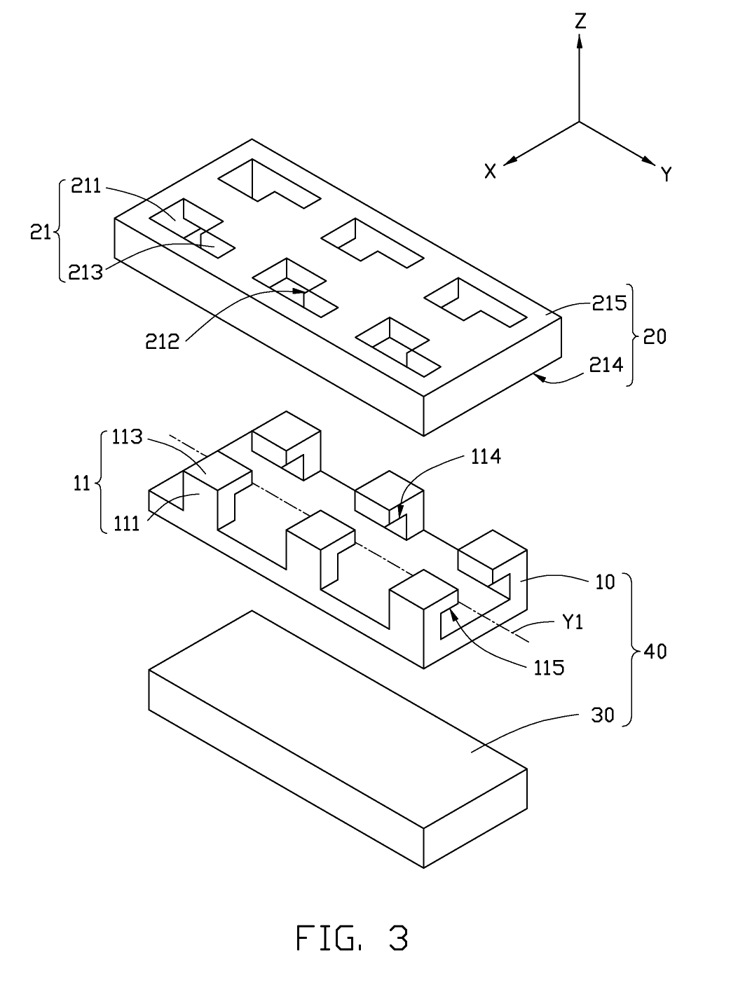

Referring to FIGS. 2 and 3, each support 100 includes a fixing board 20 fixed in the corresponding mounting hole 210, and a foot pad 40 engaging the fixing board 20. The foot pad 40 includes a connecting piece 10 and a supporting piece 30, the connecting piece 10 stacked on the supporting piece 30.

The connecting piece 10 is substantially rectangular, and is made of elastic material such as rubber, silica gel, or soft resin. The foot pad 40 further includes six latching hooks 11 extending from the connecting piece 10, and away from the supporting piece 30. Each of the latching hooks 11 is substantially L-shaped. Each of the latching hooks 11 includes a sliding portion 111 and a hook portion 113 extending from a free end and substantially perpendicular to the sliding portion 111. The sliding portion 111 is substantially rectangular-shaped. The supporting piece 30 is substantially rectangular to match the shape of the connecting piece 10, and made of any material with relatively high mechanical strength and anti-wear capability, such as polycarbonate (PC). In the illustrated embodiment, the connecting piece 10 and the supporting piece 30 are integrally formed by bi-insertion molding. It is to be understood that, in an alternative embodiment, the supporting piece 30 can be omitted.

The six latching hooks 11 are arranged on the connecting piece 10 in a matrix. In the illustrated embodiment, the three latching hooks 11 extend from a first edge of the connecting piece 10 parallel to a Y axis. The other three latching hooks 11 extend from a second edge of the connecting piece 10 opposite to the first edge. The three latching hooks 11 extending from the first edge of the connecting piece 10 and the other three latching hooks 11 extending from the second edge of the connecting piece 10 are symmetrical relative to a center axis Y1 of the connecting piece 10 along the Y axis. The hook portion 113 of each latching hook 11 extends from the free end of the sliding portion 111; and the hook portion 113 substantially bends towards the center axis Y1 of the connecting piece 10. Thus, a width of the hook portion 113 along an X axis exceeds that of the sliding portion 111. The hook portion 113 includes a resisting surface 115 facing and substantially parallel to the connecting piece 10.

The fixing board 20 is also substantially rectangular, but larger than the connecting piece 10. The fixing board 20 includes a first surface 214 and a second surface 215. The first surface 214 is closer to the connecting piece 10. The second surface 215 is opposite to the first surface 214 and is away from the connecting piece 10. The fixing board 20 defines six through holes 21 on the second surface 215 corresponding to the six latching hooks 11 of the connecting piece 10, respectively. Each of the through holes 21 includes a receiving portion 211 in which the hook portion 113 is passed through, and a latching portion 213 communicating with the receiving portion 211. The receiving portion 211 is substantially the same size as the hook portion 113 of the latching hooks 11. The width of the latching portion 213 along the X axis and the width of the sliding portion 111 of the latching hook 11 along the same direction are substantially the same, therefore, the sliding portion 111 can slidably move along the Y axis in the receiving portion 211 of the through hole 21 and be firmly engaged in the latching portion 213. The receiving portion 211 is larger than the latching portion 213. A depth of the latching portion 213 along the Z axis substantially equals a width of the sliding portion 111 along the same Z axis.

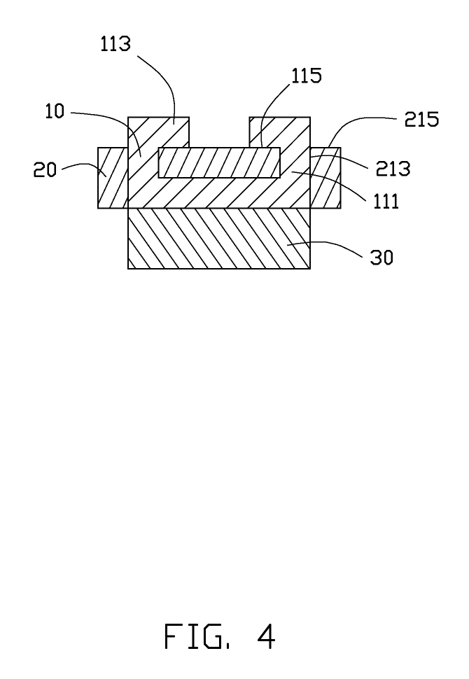

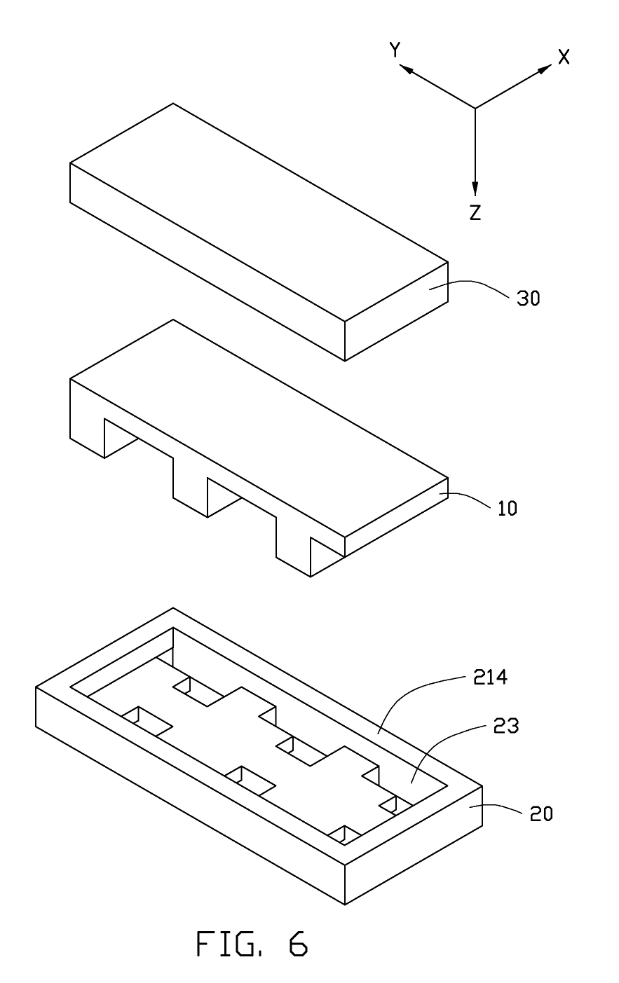

Referring to FIG. 4, the sliding portion 111 of each latching hook 11 is correspondingly fixed in the latching portion 213 of each receiving hole 21, such that the resisting surface 115 of each hook portion 113 resists the second surface 215 of the fixing board 21. In other words, each latching hook 11 is correspondingly hooked on the fixing board 20. Referring to FIG. 6, the fixing board 20 further defines a rectangular receiving depression 23 on the first surface 214 to receive at least a part of the connecting piece 10. In an alternative embodiment, the receiving depression 23 can be omitted.

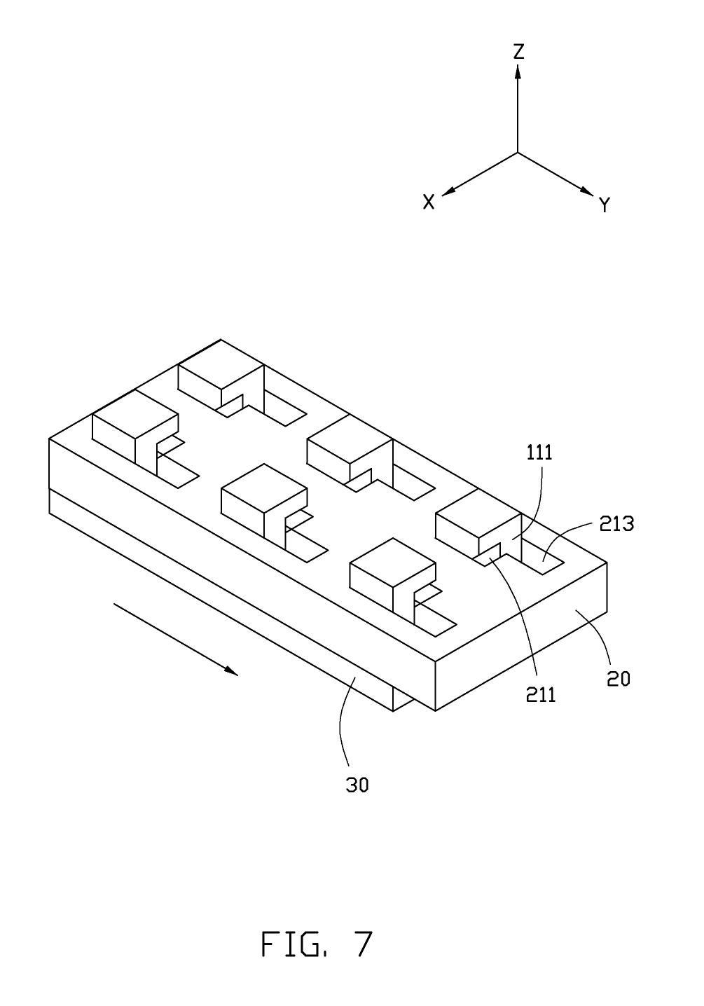

To install the support 100 onto the housing 200, the fixing board 20 is first fixed in the corresponding mounting hole 210 of the housing 200 by welding or fastener modules. The foot pad 40 then engages the fixing board 20. Because the dimensions of the fixing board 20 is larger than that of the mounting hole 210, the fixing board 20 would be abutted on a part of the housing 200 which surrounds the mounting hole 210, thus would not be pushed into the mounting hole 210. In an alternative embodiment, a piece of pressboard (not shown) can be permanently bonded to the housing 200 which then is used to attach to the fixing board 20, so as to prevent the supporting piece 30 from being pushed into the mounting hole 210. At this time, the latching hooks 11 are placed corresponding to the through holes 21, and receiving external pressure, such that the hook portions 113 pass through the corresponding receiving portion 211. Next, referring to FIG. 7, the connecting piece 10 is moved along the Y axis, such that the sliding portions 111 of the latching hook 11 are received in the corresponding latching portions 213 of the fixing board 20, and the hook portions 114 hook on to the second surface 215 of the fixing board 20. Thus, the support 100 is thereby tightly fixed to the bottom surface of the housing 200 and is able to maintain a longer service duration irrespective of environmental changes.

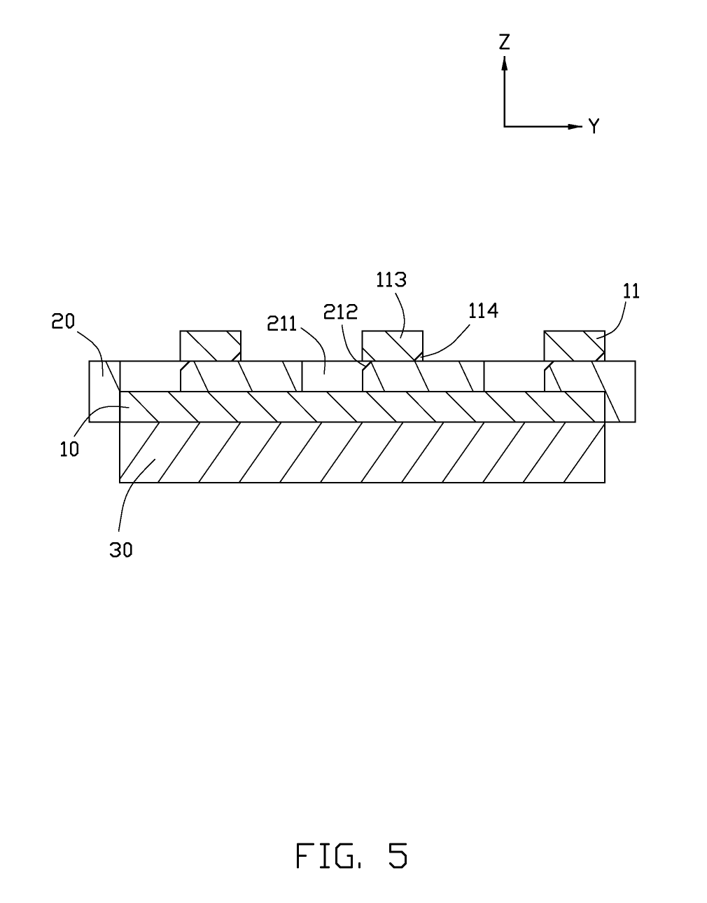

Referring to FIGS. 3 and 5 together, each through hole 21 may further include a first inclined tapered surface 212 at an inner surface of the receiving portion 211 adjacent to the second surface 215 and adjoining the latching portion 213. Referring to FIGS. 3 and 5 together, the hook portion 113 may further include a second inclined tapered surface 114 adjoining the resisting surface 115 corresponding to the first inclined tapered surface 212. When the foot pad 40 is installed onto the fixing board 20, the sliding portion 11 can easily slide into the latching portion 213 due to the first inclined tapered surface 212 and the second inclined tapered surface 114.

In an alternative embodiment, a shape of the latching hook 11 can alternatively be substantially T-shaped or Y-shaped, as long as the hook portion 113 can pass through the receiving portion 211 and fix the fixing board 20. It should be noted that the number of the latching hooks 11 and of the through holes 21 are specifically described and illustrated in the embodiment for the purpose of exemplifying various aspects of the present support 100.

Finally, while various embodiments have been described and illustrated, the disclosure is not to be construed as being limited thereto. Various modifications can be made to the embodiments by those skilled in the art without departing from the true spirit and scope of the disclosure as defined by the appended claims.

What is claimed is:

1. An electronic device, comprising:
a housing comprising a bottom surface and a mounting hole defined therein; and
a support comprising:
a fixing board and a foot pad, the fixing board fixed in the mounting hole of the housing and defining a through hole therein, the foot pad comprising:
a latching hook engaging the fixing board via the through hole, wherein the latching hook comprises a sliding portion and a hook portion fixed to a free end of the sliding portion; and the through hole comprises a receiving portion passing through the hook portion, and a latching portion communicating with the receiving portion, and the sliding portion is fixed in the latching portion such that the hook portion correspondingly hooks onto the fixing board.

2. The electronic device of claim 1, wherein the foot pad comprises a supporting piece and a connecting piece stacked thereon, and the latching hook extends from a surface of the connecting piece, and away from the supporting piece.

3. The electronic device of claim 1, wherein the foot pad is made of rubber, silica gel, or soft resin.

4. The electronic device of claim 2, wherein the connecting piece is made of rubber, silica gel, or soft resin; and the supporting piece is made of polycarbonate.

5. The electronic device of claim 1, wherein the latching hook is T-shaped, L-shaped, or Y-shaped.

6. The electronic device of claim 1, wherein the fixing board comprises a first surface adjacent to the connecting piece and a second surface opposite to the first surface, and away from the connecting piece.

7. The electronic device of claim 6, wherein the through hole further comprises a first inclined tapered surface at an inner surface of the receiving portion adjacent to the second surface and adjoining the latching portion.

8. The electronic device of claim 7, wherein the hook portion comprises a resisting surface facing and substantially parallel to the connecting piece.

9. The electronic device of claim 8, wherein the hook portion further comprises a second inclined tapered surface adjoining the resisting surface corresponding to the first inclined tapered surface.
